(19) United States
(12) Patent Application Publication
(10) Pub. No.: US 2025/0301847 A1
(43) Pub. Date: Sep. 25, 2025

(54) SUPERHYDROPHOBIC FILM FOR CONTROLLING LIFETIME OF BIODEGRADABLE ELECTRONIC DEVICE

(71) Applicant: KOREA UNIVERSITY RESEARCH AND BUSINESS FOUNDATION, Seoul (KR)

(72) Inventors: Suk Won HWANG, Seoul (KR); Gwan Jin KO, Busan (KR); Won Bae HAN, Seoul (KR)

(73) Assignee: KOREA UNIVERSITY RESEARCH AND BUSINESS FOUNDATION, Seoul (KR)

(21) Appl. No.: 19/042,794

(22) Filed: Jan. 31, 2025

(30) Foreign Application Priority Data
Mar. 19, 2024 (KR) 10-2024-0037591

(51) Int. Cl. H10H 29/853; H10H 29/854

(52) U.S. Cl. CPC H10H 29/853; H10H 29/854

(57) ABSTRACT

Disclosed is a superhydrophobic film. The superhydrophobic film includes: a base film; and a plurality of micro-pillars formed on the base film, wherein the base film and the micro-pillar include a biodegradable polymer and nanoparticles.

### CROSS-REFERENCE TO RELATED APPLICATION(S)

This application claims the benefit under 35 USC 119(a) of Korean Patent Application No. 10-2024-0037591, with the Korean Intellectual Property Office filed on Mar. 19, 2024, the disclosure of which is incorporated herein by reference in its entirety.

### BACKGROUND OF THE INVENTION

### 1. Field of the Invention

The present invention relates to a superhydrophobic film, and more particularly, to a superhydrophobic film in which micro-pillars are formed on a film based on a biodegradable polymer and nanoparticles, so that water permeation and diffusion may be controlled.

### 2. Description of the Related Art

Biodegradable electronic devices (transient electronics) correspond to semiconductor technologies in which the electronic devices are dissolved, decomposed, and separated in the body or environment to dissipate their physical states and electrical functions, which have brought about innovation in the fields of biomedical and eco-friendly electronic systems. Such dissipation characteristics of the electronic devices are exhibited after stably performing original functions of the devices for a predetermined time, and in order for the electronic devices to stably perform functions thereof, a technology capable of controlling a functional lifetime is required.

Accordingly, in order to control the lifetime of the electronic device, various protective film technologies based on various organic and inorganic materials are being reported. A protective film of the biodegradable electronic device is applied to the skin, body organs, and the like so as to be attachable, implantable, and edible. To this end, flexibility and stretchability that allows a function to be performed with stable performance even under various and frequent movements and deformations are essential. However, existing biodegradable polymer materials that are mainly used as materials for the protective film of the biodegradable electronic device have difficulties in ensuring a sufficient lifetime of the electronic device due to high water permeability.

In order to solve the above problems, organic and inorganic multilayer structures using an organic thin film layer having low permeability have been reported. However, the above structures have limitations that their application to the body and various environments, which move or stretch over time, is hindered due to rigid and brittle mechanical properties thereof.

Therefore, the development of protective film technologies and relevant technologies that simultaneously satisfy flexible and highly stretchable characteristics of biodegradable electronic devices and high protective film properties capable of stably controlling a lifetime according to a purpose is required.

### SUMMARY OF THE INVENTION

The present invention provides a superhydrophobic film capable of delaying a time for water molecules to permeate into the superhydrophobic film.

In addition, the present invention provides a superhydrophobic film capable of limiting diffusion of water.

In addition, the present invention provides a superhydrophobic film capable of increasing a diffusion path of a water molecule within the superhydrophobic film.

According to an embodiment of the present invention, a superhydrophobic film includes: a base film; and a plurality of micro-pillars formed on the base film, wherein the base film and the micro-pillar include a biodegradable polymer and nanoparticles.

In addition, the nanoparticle may be formed of silicon oxide or polytetrafluoroethylene (PTFE).

In addition, the nanoparticle may have an aspect ratio of 1 and a size of 100 to 200 nm.

In addition, a volume fraction of the nanoparticles to the polymer may be 40%.

In addition, the nanoparticle may be provided as a flake having an aspect ratio of 2 to 100, a width of 10 to 30 μm, and a thickness of 100 to 300 nm.

In addition, a volume fraction of the nanoparticles to the polymer may be 20%.

According to an embodiment of the present invention, a superhydrophobic light emitting module includes: a first superhydrophobic film; a second superhydrophobic film facing the first superhydrophobic film; an electrode provided on one surface of the first superhydrophobic film facing the second superhydrophobic film; and a light emitting device connected to the electrode, and configured to generate light by a current applied from the electrode, wherein each of the first superhydrophobic film and the second superhydrophobic film includes: a base film; and a plurality of micro-pillars formed on the base film, and the base film and the micro-pillar include a biodegradable polymer and nanoparticles.

According to an embodiment of the present invention, a method for manufacturing a superhydrophobic film includes: preparing a mixed solution by mixing nanoparticles with a solution in which a biodegradable polymer is dissolved in an organic solvent; preparing a superhydrophobic film by pouring the mixed solution into a mold; and separating the superhydrophobic film from the mold, wherein the superhydrophobic film separated from the mold includes: a base film; and a plurality of micro-pillars formed on the base film.

In addition, the biodegradable polymer may be dissolved in the organic solvent at a mass ratio of 10 to 20, and the nanoparticles may be mixed with the solution at a volume fraction of 10 to 40.

In addition, the nanoparticle may have an aspect ratio of 1 and a size of 100 to 200 nm.

In addition, the nanoparticle may be provided as a flake having an aspect ratio of 2 to 100, a width of 10 to 30 μm, and a thickness of 100 to 300 nm.

According to the present invention, micro-pillars may be formed in a superhydrophobic film to allow water molecules to float on a surface of the superhydrophobic film, so that a surface area in which the water molecule make contact with the superhydrophobic film before the water molecule is completely absorbed by the superhydrophobic film may be reduced, and the water molecule may form a high contact angle with the superhydrophobic film, and thus a time for the water molecules to permeate into the surface of the superhydrophobic film can be delayed.

In addition, according to the present invention, the superhydrophobic film may include a base film and micro-pillars, which include nanoparticles in a biodegradable polymer, so that diffusion of water can be limited.

In addition, according to the present invention, a diffusion path of a water molecule within the superhydrophobic film can be controlled by an aspect ratio and a size of the nanoparticle.

### BRIEF DESCRIPTION OF THE DRAWINGS

FIG. 1 is a schematic view and an enlarged view showing a superhydrophobic film according to an embodiment of the present invention.

FIG. 2 is a cross-section view showing the superhydrophobic film according to the embodiment of the present invention.

FIG. 3 is a cross-section view showing the superhydrophobic film according to a volume fraction of nanoparticles to a biodegradable polymer according to the embodiment of the present invention, which is an enlarged image obtained by using a scanning electron microscope (SEM).

FIG. 4 is an enlarged image of micro-pillars within the CAP/S40 film of FIG. 3, which is obtained by using a scanning electron microscope (SEM).

FIG. 5 is a flowchart showing a method for manufacturing a superhydrophobic film according to an embodiment of the present invention.

FIG. 6 is a view sequentially showing processes of manufacturing a superhydrophobic film by using a mixed solution according to an embodiment of the present invention.

FIG. 7 is a view showing superhydrophobic performance of the superhydrophobic film according to the embodiment of the present invention.

FIG. 8 is a view showing water permeability of FIG. 7.

FIG. 9 is an image showing an elastic response to tensile strain of a CAP/P40 film according to an embodiment of the present invention.

FIG. 10 is a graph showing stress and strain of the superhydrophobic film according to the volume fraction of the nanoparticles mixed in the biodegradable polymer according to the embodiment of the present invention.

FIG. 11 is a graph showing a modulus and toughness according to a volume fraction of PTFE nanoparticles of the superhydrophobic film according to the embodiment of the present invention.

FIG. 12 is a view showing a water molecule diffusion control mechanism of the superhydrophobic film according to the embodiment of the present invention.

FIG. 13 is a view showing water molecule diffusion control capability according to an aspect ratio of the nanoparticle mixed in the superhydrophobic film according to the embodiment of the present invention.

FIG. 14 is a graph showing a water contact angle according to presence or absence of the micro-pillars in the superhydrophobic film according to the embodiment of the present invention.

FIG. 15 is a graph showing a water contact angle according to tensile strain of the superhydrophobic film according to the embodiment of the present invention.

FIG. 16 is an image showing water-repellent performance of the CAP/P40 film of FIG. 15 according to tensile strain, which is obtained by using a confocal microscope.

FIG. 17 is a graph showing relative diffusivity according to the aspect ratio and the volume fraction of the nanoparticles mixed in the superhydrophobic film according to the embodiment of the present invention.

FIG. 18 is a graph showing relative diffusivity according to the volume fraction of the PTFE nanoparticles of the superhydrophobic film according to the embodiment of the present invention.

FIG. 19 is a graph showing the volume fraction of the nanoparticles according to tension of the CAP/P40 film of FIG. 18.

FIG. 20 is a graph showing relative diffusivity according to the tension of the CAP/P40 film of FIG. 18.

FIG. 21 is an exploded perspective view (A) and an optical image (B) showing a superhydrophobic light emitting module according to an embodiment of the present invention.

FIG. 22 is a cross-section view showing a superhydrophobic light emitting module according to another embodiment of the present invention.

FIG. 23 is a view showing tension test performance of the superhydrophobic light emitting module according to the embodiment of the present invention.

FIG. 24 is a graph showing the tension test performance of FIG. 23.

FIG. 25 is an image showing water permeability of the superhydrophobic light emitting module based on a CAP/P40 film according to the embodiment of the present invention.

FIG. 26 is a graph showing water blocking characteristics of FIG. 25, which is measured by infrared spectroscopy (IR spectrum).

FIG. 27 is a graph showing solubility of superhydrophobic light emitting modules according to various embodiments.

FIG. 28 is a graph showing encapsulation performance according to various tensile strain of the superhydrophobic light emitting module based on the CAP/P40 film according to the embodiment of the present invention.

### DETAILED DESCRIPTION OF THE INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly formed on another element, or a third element may be interposed between one element and another element. Further, in the drawings, thicknesses of films and regions are exaggerated for effective description of the technical contents.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. In addition, the term “connection” used herein is used to include both indirect and direct connections of a plurality of elements.

Further, in the following description of the present invention, detailed descriptions of known functions or configurations incorporated herein will be omitted when they may make the gist of the present invention unnecessarily unclear.

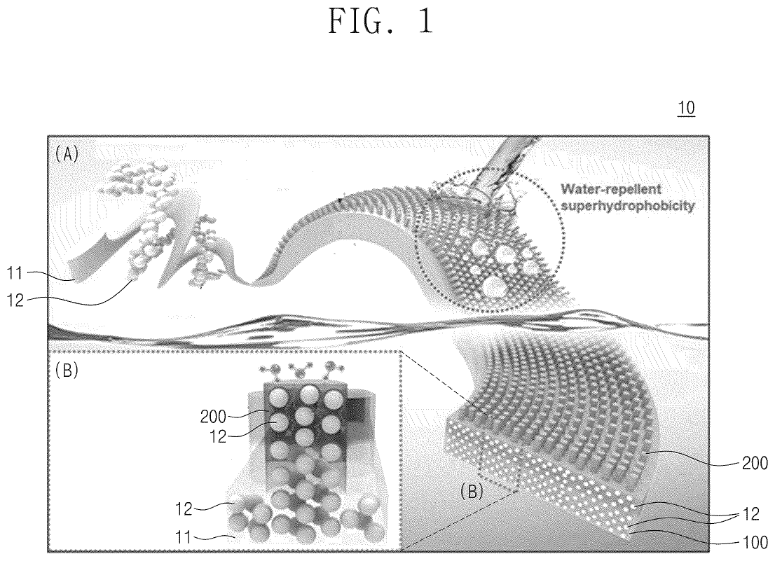

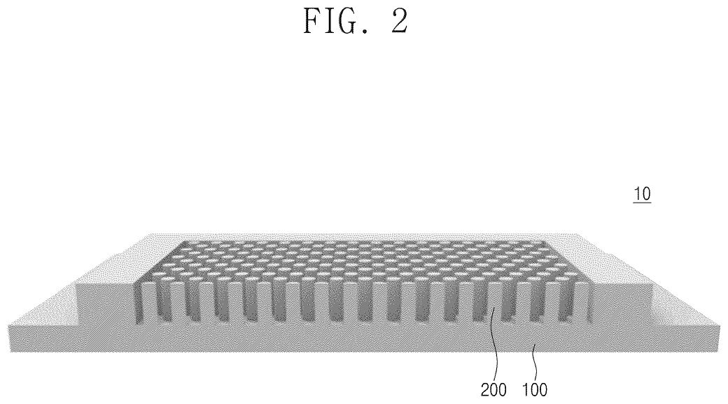

FIG. 1 is a schematic view and an enlarged view showing a superhydrophobic film according to an embodiment of the present invention. (A) is a schematic view showing a superhydrophobic film, and (B) is an enlarged view showing a partial region of the superhydrophobic film. In addition, FIG. 2 is a cross-section view showing the superhydrophobic film according to the embodiment of the present invention.

Referring to FIGS. 1 and 2, a superhydrophobic film 10 may provide a superhydrophobic protective film capable of delaying a time for water molecules to permeate into a surface of the film by using a plurality of micro-pillars formed on one surface of the film based on a biodegradable polymer and nanoparticles, which limit diffusion of the water molecules.

The superhydrophobic film 10 may have a predetermined area, and may be provided in the form of a thin film. The superhydrophobic film 10 may be provided as a composite material of a biodegradable elastic polymer 11 and nanoparticles 12. According to an embodiment, the biodegradable elastic polymer may be formed of poly(lactide-co-ε-caprolactone) (PLCL). The biodegradable elastic polymer is not limited thereto, and various biodegradable elastic polymers other than the PLCL may be used.

The nanoparticles may be formed of silicon oxide or polytetrafluoroethylene (PTFE). According to one embodiment, the nanoparticles may be formed of silicon dioxide or PTFE having an aspect ratio of 1 and a size of 100 to 200 nm. According to another embodiment, the nanoparticle may be provided as a silicon dioxide flake having an aspect ratio of 2 to 100, a width of 10 to 30 μm, and a thickness of 100 to 300 nm.

The superhydrophobic film 10 may include a base film 100 and micro-pillars 200.

The base film 100 may have a predetermined area, and may be provided as a film having a thin thickness.

The micro-pillars 200 may have a predetermined height, and may be formed on one surface of the base film 100. A plurality of micro-pillars may be provided so as to be uniformly arranged. According to an embodiment, the micro-pillars may be provided integrally with the base film. The micro-pillars may be provided as cylinders having a predetermined length.

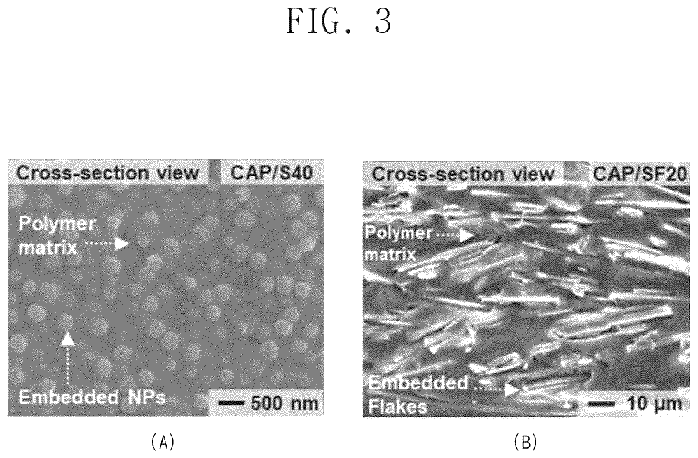

FIG. 3 is a cross-section view showing the superhydrophobic film according to a volume fraction of nanoparticles to a biodegradable polymer according to the embodiment of the present invention, which is an enlarged image obtained by using a scanning electron microscope (SEM). (A) is a cross-section view showing the superhydrophobic film (CAP/S40) when silicon dioxide nanoparticles (NPs) are mixed in a biodegradable polymer matrix on which micro-pillars are formed at a volume fraction of 40%, and (B) is a cross-section view showing the superhydrophobic film (CAP/SF20) when nanoparticles, which are provided as flakes (Flakes), are mixed in a biodegradable polymer on which micro-pillars are formed at a volume fraction of 20%.

Referring to FIG. 3, it may be found that an inside of the superhydrophobic film has different structures according to a shape of the nanoparticle and a volume fraction of the nanoparticles to the biodegradable polymer. Accordingly, it may be found that a diffusion path of a water molecule may vary according to the shape of the nanoparticle and the volume fraction of the nanoparticles to the biodegradable polymer.

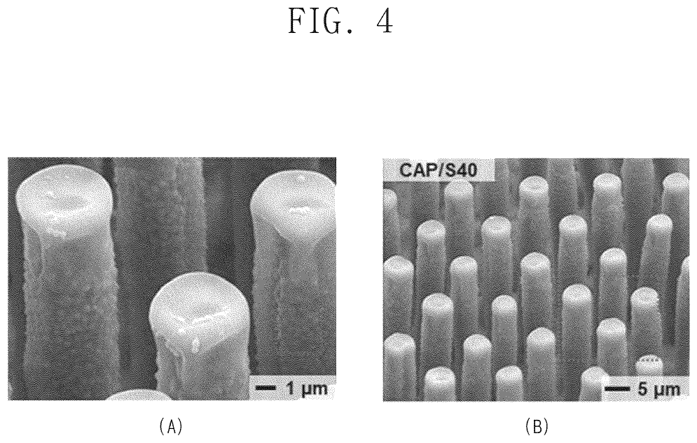

FIG. 4 is an enlarged image of micro-pillars within the CAP/S40 film of FIG. 3, which is obtained by using a scanning electron microscope (SEM). (A) shows a CAP/S40 film when enlarged to 1 μm, and (B) shows the CAP/S40 film when enlarged to 5 μm.

Referring to FIG. 4, when the silicon dioxide nanoparticles are mixed in the biodegradable polymer on which the micro-pillars are formed at the volume fraction of 40%, it may be found that a plurality of nanoparticles having a diameter of 200 nm or less are formed on the surface of the superhydrophobic film, and a plurality of micro-pillars having a diameter of 5 μm and a height of 30 μm are uniformly regularly arranged.

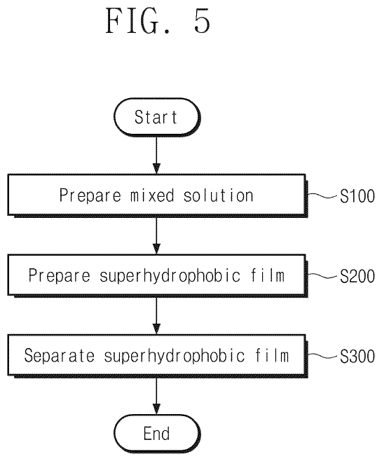

FIG. 5 is a flowchart showing a method for manufacturing a superhydrophobic film according to an embodiment of the present invention.

Referring to FIG. 5, a method for manufacturing a superhydrophobic film may include preparing a mixed solution (S100), preparing a superhydrophobic film (S200), and separating the superhydrophobic film (S300).

In the preparing of the mixed solution (S100), a biodegradable polymer may be dissolved in an organic solvent, and nanoparticles are mixed with a resulting solution, so that the mixed solution may be prepared. According to an embodiment, the organic solvent may include dimethyl formamide (DMF), dimethyl sulfoxide, and ethyl acetate. The biodegradable polymer may be dissolved in the organic solvent at a mass ratio of 10 to 20 w/v % (weight per volume), and the nanoparticles may be mixed with the solution in which the biodegradable polymer is dissolved at a volume fraction of 10 to 40%. According to one embodiment, the nanoparticles may be formed of silicon dioxide or PTFE having an aspect ratio of 1 and a size of 100 to 200 nm, and according to another embodiment, the nanoparticle may be provided as a silicon dioxide flake having an aspect ratio of 2 to 100, a width of 10 to 30 μm, and a thickness of 100 to 300 nm.

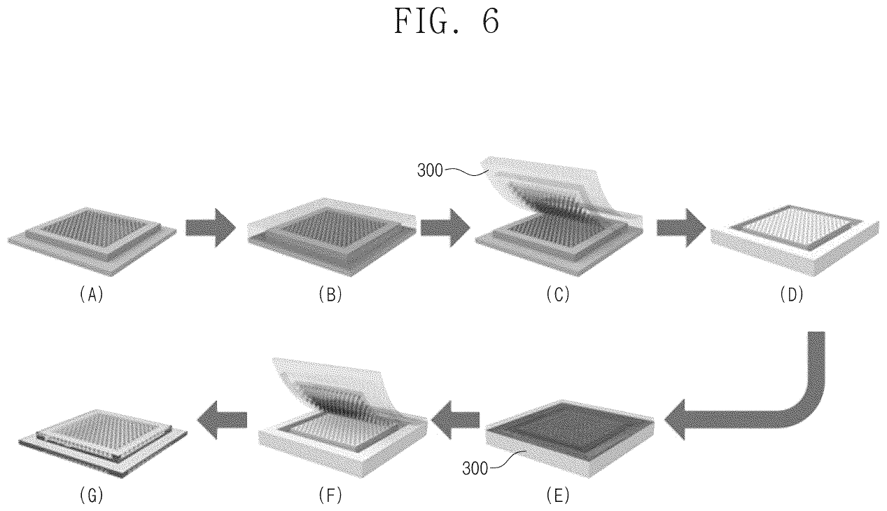

FIG. 6 is a view sequentially showing processes of manufacturing a superhydrophobic film by using a mixed solution according to an embodiment of the present invention.

Referring to FIG. 6, first, a mold may be prepared to manufacture the superhydrophobic film.

Referring to (A) to (D), regarding a mold 300, a microstructure may be formed on a silicon substrate by using a photolithography process and a dry etch process, and a PDMS mold 300 may be prepared by using polydimethylsiloxane (PDMS). In addition, the PDMS mold 300 may be separated from the silicon substrate, so that the PDMS mold 300 for manufacturing the superhydrophobic film 10 may be finished.

Referring to (E) to (G), the nanoparticles 12 within the mixed solution may be uniformly dispersed by using a magnetic stirrer. The mixed solution may be stirred at 70 to 90° C. for 11 to 13 h.

The mixed solution that has been stirred may be poured into the PDMS mold 300, and a superhydrophobic film having micro-pillars may be manufactured through a solution casting process.

According to an embodiment, the micro-pillars may have a diameter of 3 to 5 μm, a height of 20 to 30 μm, and an interval of 3 to 5 μm. Thereafter, the superhydrophobic film 10 may be dried, and when the drying is completed, the superhydrophobic film 10 may be separated from the mold 300. According to an embodiment, the superhydrophobic film may be dried at 70 to 90° C. for 11 to 13 h.

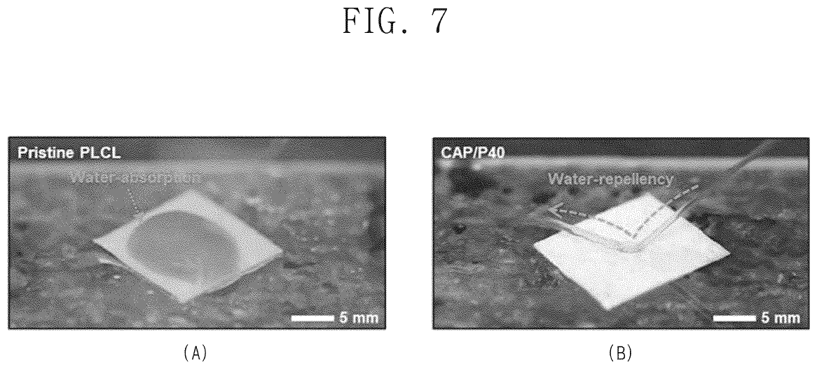

FIG. 7 is a view showing superhydrophobic performance of the superhydrophobic film according to the embodiment of the present invention. (A) shows superhydrophobic performance of a biodegradable polymer film (Pristine PLCL) without micro-pillars according to a comparative example, and (B) shows superhydrophobic performance of the superhydrophobic film (CAP/P40) in which the PTFE nanoparticles are mixed in the biodegradable polymer on which the micro-pillars are formed at the volume fraction of 40% according to the embodiment of the present invention.

Referring to FIG. 7, when water including a blue dye is sprayed on surfaces of the superhydrophobic films of (A) and (B), it may be found that the water with the blue dye adheres to the biodegradable polymer film, whereas the water with the blue dye is repelled from the superhydrophobic film in which the PTFE nanoparticles are mixed in the biodegradable polymer on which the micro-pillars are formed at the volume fraction of 40%.

FIG. 8 is a view showing water permeability of FIG. 7. (A) is a cross-section view when water is dropped on a film in which Pristine PLCL is mixed with cobalt chloride (CoCl₂) particles according to a comparative example, and (B) is a cross-section view when water is dropped on a superhydrophobic film in which CAP/P40 is mixed with cobalt chloride particles according to an embodiment of the present invention.

Referring to FIG. 8, in order to determine water permeability of a superhydrophobic film, cobalt chloride (CoCl₂), which is changed from blue to red by chemical reaction with water molecules, may be mixed with each of Pristine PLCL and CAP/P40, and water (Water) may be dropped on the Pristine PLCL film and the CAP/P40 film mixed with cobalt chloride. In (A), the water was placed on the Pristine PLCL film, and the water completely permeated into the Pristine PLCL film after 12 hours (Rapid permeation), so that the film changed to red in response to the cobalt chloride mixed with the Pristine PLCL film. On the contrary, in (B), the water was placed on the CAP/P40 film, and the CAP/P40 film still blocked water permeation even after 12 hours (Slow permeation), so that the color of the film was not changed since the sprayed water did not react with the cobalt chloride mixed with the CAP/P40 film. Accordingly, protective performance of the CAP/P40 film, which delays permeation and internal penetration of water.

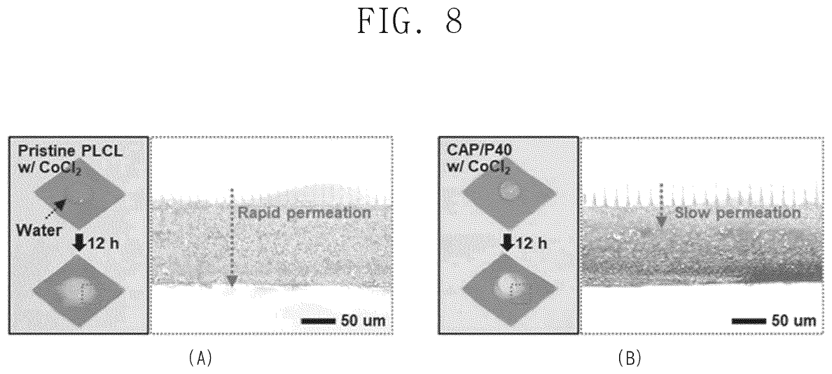

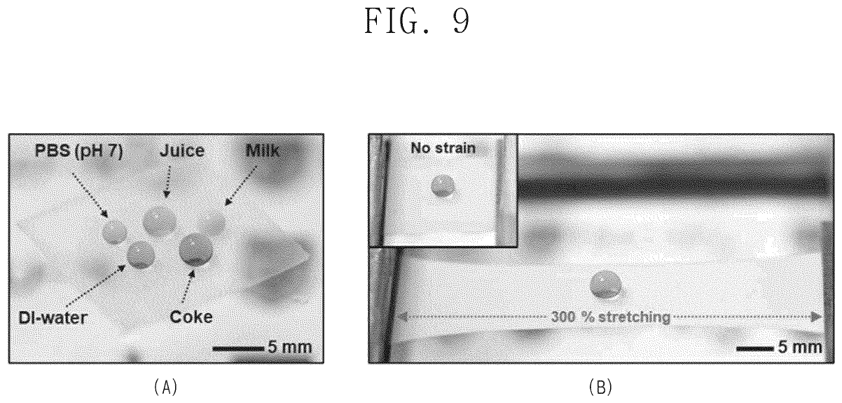

FIG. 9 is an image showing an elastic response to tensile strain of a CAP/P40 film according to an embodiment of the present invention. (A) shows reaction between the surface of the CAP/P40 film and liquids when various liquids are placed on the CAP/P40 film, and (B) shows reaction between the surface of the CAP/P40 film and DI-water when the DI-water is placed on the CAP/P40 film, and the CAP/P40 film is stretched by 300% (300% stretching).

Referring to (A) of FIG. 9, when the various liquids (DI-water, PBS (pH 7), Juice, Milk, and Coke) are dropped on the CAP/P40 film, it may be found that each of the liquids maintains a shape thereof without being absorbed by the CAP/P40 film. Referring to (B), when the CAP/P40 film is stretched by 300%, the it may be found that the CAP/P40 film is flexibly stretched without being broken or cracked so as to stably maintain superhydrophobicity, so that the DI-water placed on the surface of the CAP/P40 film also maintains a shape thereof without being absorbed by the CAP/P40 film stretched by 300%.

Such an elastic response of the CAP/P40 film to 300% external strain may be attributed to excellent elasticity of PLCL due to physical cross-linking of hard (L-lactide) and soft (C-caprolactone) regions.

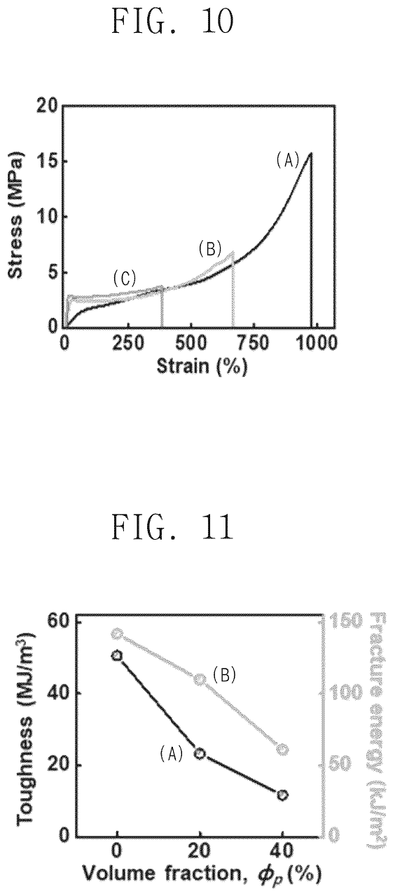

FIG. 10 is a graph showing stress and strain of the superhydrophobic film according to the volume fraction of the nanoparticles mixed in the biodegradable polymer according to the embodiment of the present invention. (A) shows stress of a superhydrophobic film (CAP/PO) on which micro-pillars are formed on a biodegradable polymer, (B) shows stress of the superhydrophobic film (CAP/P20) on which the PTFE nanoparticles are mixed in the biodegradable polymer on which the micro-pillars are formed at the volume fraction of 20%, and (C) shows stress of the superhydrophobic film (CAP/P40) on which the PTFE nanoparticles are mixed in the biodegradable polymer on which the micro-pillars are formed at the volume fraction of 40%.

Referring to FIG. 10, it may be found that (A) without the PTFE nanoparticles exhibits excellent strain and stress, and (C) to which the PTFE nanoparticles are mixed by 40% exhibits the lowest strain and stress.

Accordingly, it may be found that while elasticity is gradually decreased as an addition amount of the PTFE nanoparticles increases, the superhydrophobic film (CAP/P40) may still be deformed by up to 400% even when the PTFE nanoparticles are mixed in the biodegradable polymer at the volume fraction of 40%, that is, a maximum amount.

FIG. 11 is a graph showing a modulus and toughness according to a volume fraction of PTFE nanoparticles of the superhydrophobic film according to the embodiment of the present invention. (A) shows toughness (Toughness) of the superhydrophobic film according to the volume fraction (Volume Fraction) of the PTFE nanoparticles, and (B) shows fracture energy (Fracture energy) of the superhydrophobic film according to the volume fraction (Volume Fraction) of the PTFE nanoparticles.

Referring to FIG. 11, it may be found that an increase in the volume fraction of the PTFE nanoparticles mixed in the biodegradable polymer on which the micro-pillars are formed reduces the toughness (A) and the fracture energy (B).

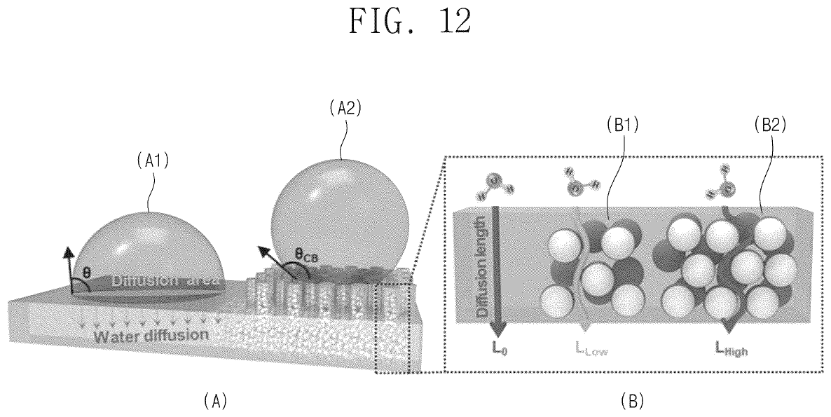

FIG. 12 is a view showing a water molecule diffusion control mechanism of the superhydrophobic film according to the embodiment of the present invention. (A) shows a water molecule diffusion control mechanism of the micro-pillars in the superhydrophobic film, and (B) shows a water molecule diffusion control mechanism of the nanoparticles in the superhydrophobic film.

Referring to FIG. 12, it may be found that water molecules in (A1) makes direct contact with the film surface without the micro-pillars so that water diffusion (Water diffusion) is performed at a low contact angle (θ) over a wide diffusion area (Diffusion area), and it may be found that water molecules in (A2) float on the surface of the superhydrophobic film since the micro-pillars that induce a Cassie-Baxter state in the superhydrophobic film are formed so that a surface area in which the water molecules make contact with the superhydrophobic film before the water molecule is completely absorbed (Wenzel State) by the superhydrophobic film is reduced, and the water molecule forms a high contact angle with the superhydrophobic film, and thus a time for the water molecules to permeate into the superhydrophobic film is delayed, thereby controlling diffusion of the water molecules.

In (B), the nanoparticles mixed inside the superhydrophobic film may act as physical obstacles in the diffusion path (Diffusion length) of the water molecules, so that the diffusion path of the water molecules within the superhydrophobic film may be increased to limit the diffusion of the water molecules. Accordingly, a path through which the water molecules may permeate may be increased more in (B2) in which a ratio of the nanoparticles within the superhydrophobic film is large than in (B1), so that the diffusion of the water molecules may be further limited.

FIG. 13 is a view showing water molecule diffusion control capability according to an aspect ratio of the nanoparticle mixed in the superhydrophobic film according to the embodiment of the present invention. (A) shows the diffusion path (Diffusion length, L) of the water molecule in nanoparticles having an aspect ratio of 1, and (B) shows the diffusion path of the water molecule in nanoparticles, which are flakes, having an aspect ratio of 2 to 100.

Referring to FIG. 13, an aspect ratio of a nanoparticle may vary according to a shape including a width and a thickness of the nanoparticle mixed in the superhydrophobic film, and the diffusion path of the water molecule may be increased or decreased according to the aspect ratio of the nanoparticle. It may be found that the water molecule diffusion path (B) in the superhydrophobic film in which the nanoparticles, which are flakes, having the aspect ratio of 2 to 100 are mixed is longer than the water molecule diffusion path (A) in the superhydrophobic film in which the nanoparticles having the aspect ratio of 1 are mixed. Accordingly, it may be found that the water molecule diffusion path within the superhydrophobic film is gradually increased as the aspect ratio of the nanoparticles mixed in the superhydrophobic film increases, which is proportional to water molecule diffusion control capability.

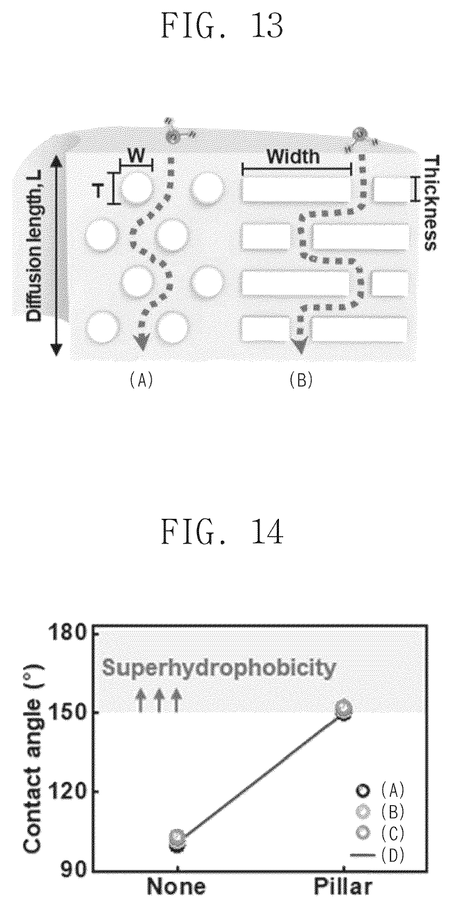

FIG. 14 is a graph showing a water contact angle according to presence or absence of the micro-pillars in the superhydrophobic film according to the embodiment of the present invention. (A) shows a water contact angle (Contact angel) according to presence or absence of the micro-pillars in the superhydrophobic film (CAP/PO) formed of the biodegradable polymer, (B) shows a water contact angle according to presence or absence of the micro-pillars in the superhydrophobic film (CAP/P20) in which the PTFE nanoparticles are mixed with the biodegradable polymer at the volume fraction of 20%, (C) shows a water contact angle according to presence or absence of the micro-pillars in the superhydrophobic film (CAP/P40) in which the PTFE nanoparticles are mixed with the biodegradable polymer at the volume fraction of 40%, and (D) shows a water contact angle estimated by a Cassie-Baxter (CB) model.

Referring to FIG. 14, it may be found that the water contact angle representing superhydrophobicity is larger in a superhydrophobic film having a micro-pillar structure (Pillar) than in a superhydrophobic film without the micro-pillar structure (None). Accordingly, it may be found that hydrophobicity of the superhydrophobic film is increased more by forming the micro-pillars on the surface of the superhydrophobic film than by increasing a mixing ratio of the PTFE nanoparticles in the biodegradable polymer.

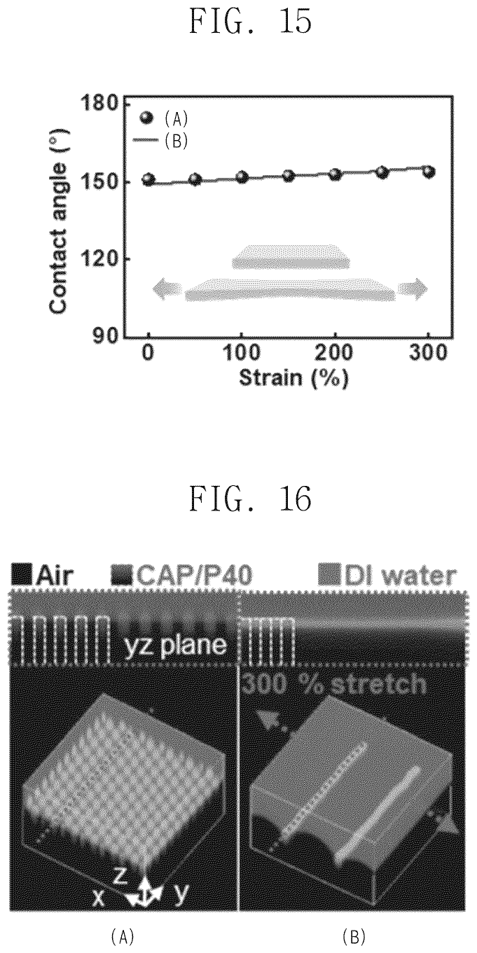

FIG. 15 is a graph showing a water contact angle according to tensile strain of the superhydrophobic film according to the embodiment of the present invention. (A) shows a water contact angle (Contact angle) of the superhydrophobic film (CAP/P40) in which the PTFE nanoparticles are mixed with the biodegradable polymer at the volume fraction of 40%, and (B) shows a water contact angle estimated by a Cassie-Baxter (CB) model.

Referring to FIG. 15, even when the superhydrophobic film (CAP/P40) is stretched up to a maximum of 300%, it may be found that the water contact angle of the superhydrophobic film (CAP/P40) has a value that is similar to a value of the water contact angle of the Cassie-Baxter model, and superhydrophobicity is maintained without a significant change.

FIG. 16 is an image showing water-repellent performance of the CAP/P40 film of FIG. 15 according to tensile strain, which is obtained by using a confocal microscope. (A) shows a superhydrophobic film structure after immersing the CAP/P40 film in deionized water (DI-water), and (B) shows a superhydrophobic film structure after stretching the CAP/P40 film by 300% and immersing the CAP/P40 film in the DI-water.

Referring to FIG. 16, in order to observe water-repellent performance of the CAP/P40 film according to tensile strain by using a confocal microscope, 0.1 to 0.5 mol % of a Nile red dye may be mixed with each of the CAP/P40 film and the CAP/P40 stretched by 300%, and each of the CAP/P40 film and the CAP/P40 stretched by 300% may be immersed in the DI-water mixed with 0.1 to 0.5 mol % of an Alexa 488 dye. It may be found that even when the CAP/P40 film is immersed in the deionized water (A) or immersed in the deionized water after 300% stretching (B), a water-repellent function is still maintained, and a diffusion area is reduced.

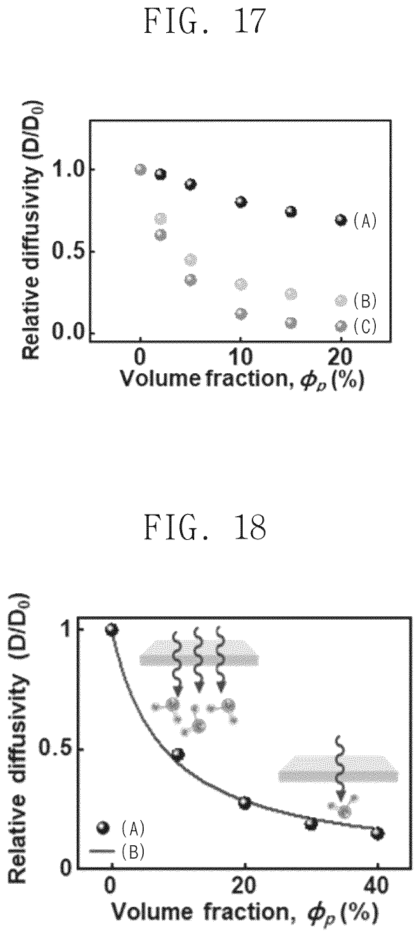

FIG. 17 is a graph showing relative diffusivity according to the aspect ratio and the volume fraction of the nanoparticles mixed in the superhydrophobic film according to the embodiment of the present invention. (A) shows relative diffusivity (Relative diffusivity) according to the volume fraction of nanoparticles having an aspect ratio of 1 (Particles, W/T=1), (B) shows relative diffusivity according to the volume fraction of nanoparticles, which are flakes, having an aspect ratio of 50 (Flakes, W/T=50), and (C) shows relative diffusivity according to the volume fraction of nanoparticles, which are flakes, having an aspect ratio of 100 (Flakes, W/T=100).

Referring to FIG. 17, it may be found that the relative diffusivity within the superhydrophobic film is gradually decreased as the mixing volume fraction of the nanoparticles in the superhydrophobic film increases, and an effect of decreasing the relative diffusivity by the nanoparticles is gradually increased as the aspect ratio of the nanoparticles in the superhydrophobic film increases.

FIG. 18 is a graph showing relative diffusivity according to the volume fraction of the PTFE nanoparticles of the superhydrophobic film according to the embodiment of the present invention. (A) shows relative diffusivity of a superhydrophobic film (CAP/P) according to the volume fraction of the PTFE nanoparticles mixed in the biodegradable polymer on which the micro-pillars are formed, and (B) shows relative diffusivity estimated by a Higuchi model by using a Higuchi constant of 3.6.

Referring to FIG. 18, it may be found that in (A), the relative diffusivity of the superhydrophobic film according to volume fractions of the PTFE nanoparticles of 0%, 20%, and 40% with respect to the biodegradable polymer is decreased in proportion to the volume fraction of the PTFE nanoparticles. In particular, it may be found that the relative diffusivity is significantly decreased to a value that is less than 0.15 at the volume fraction of the PTFE nanoparticles of 40% with respect to the biodegradable polymer. This is because the relative diffusivity is determined by the increase in the diffusion path of the water molecules within the superhydrophobic film according to the mixing volume fraction of the nanoparticles in the CAP/P, which was verified by the Higuchi model.

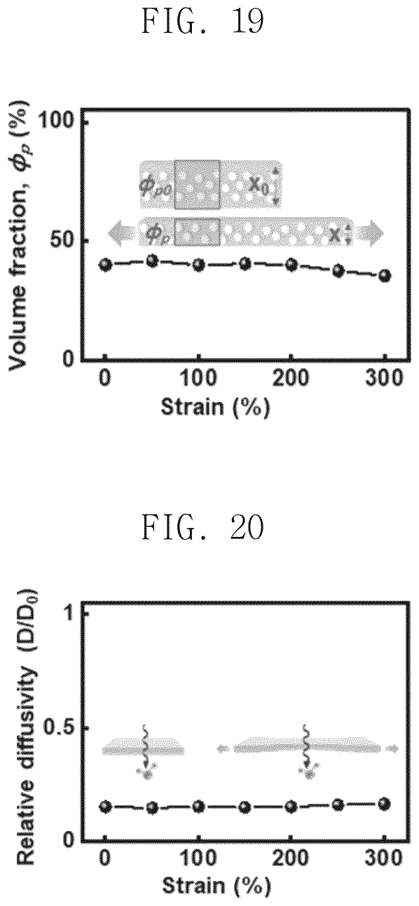

FIG. 19 is a graph showing the volume fraction of the nanoparticles according to tension of the CAP/P40 film of FIG. 18.

Referring to FIG. 19, it may be found that the superhydrophobic film in which the volume fraction of the PTFE nanoparticles with respect to the biodegradable polymer is 40% has a volume fraction (Volume fraction) that is not significantly changed at strain (Strain) of 30 to 300%. Accordingly, it may be found that the CAP/P40 film is not significantly affected by external stretching deformation.

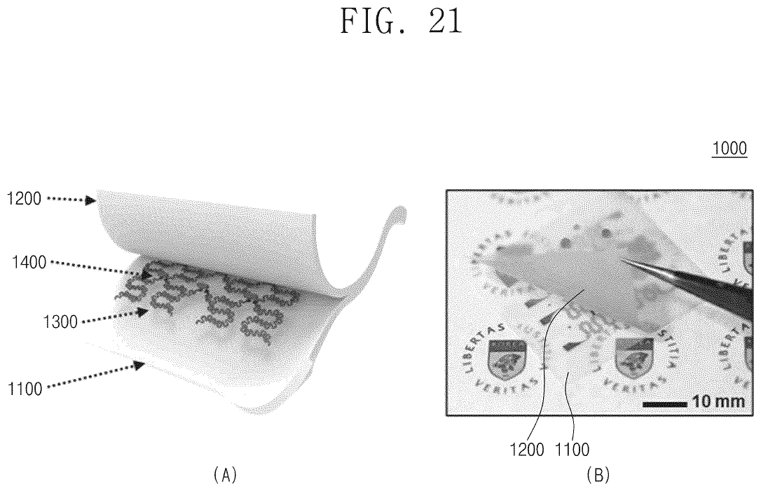

FIG. 20 is a graph showing relative diffusivity according to the tension of the CAP/P40 film of FIG. 18.

Referring to FIG. 20, it may be found that the superhydrophobic film in which the volume fraction of the PTFE nanoparticles with respect to the biodegradable polymer is 40% has relative diffusivity (Relative diffusivity) that is nearly constant without being significant changed at strain (Strain) of 30 to 300%.

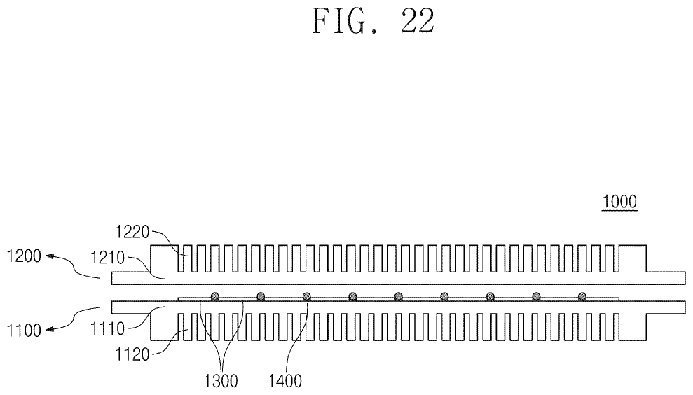

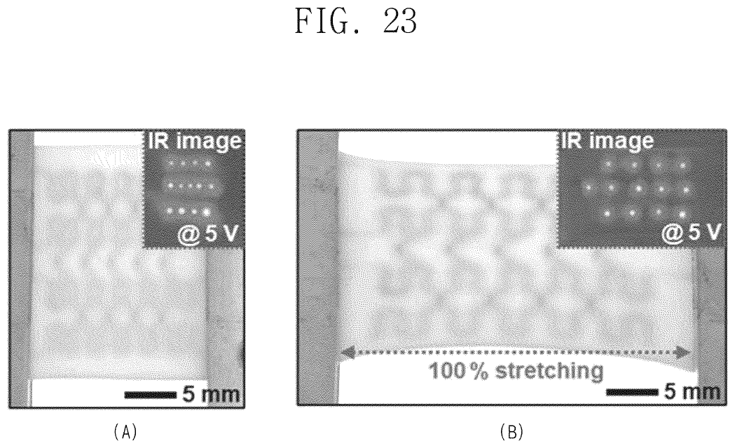

FIG. 21 is an exploded perspective view (A) and an optical image (B) showing a superhydrophobic light emitting module according to an embodiment of the present invention, and FIG. 22 is a cross-section view showing a superhydrophobic light emitting module according to another embodiment of the present invention.

Referring to FIGS. 21 and 22, a superhydrophobic light emitting module 1000 may waterproof and encapsulate an electrode and a light emitting device with a pair of superhydrophobic films having one surface on which a plurality of micro-pillars are formed based on a biodegradable polymer and nanoparticles.

The superhydrophobic light emitting module 1000 may include a first superhydrophobic film 1100, a second superhydrophobic film 1200, an electrode 1300, and a light emitting device 1400.

The first superhydrophobic film 1100 may have a predetermined area, and may be provided in the form of a thin film. The first superhydrophobic film 1100 may be provided as a composite material of a biodegradable elastic polymer and nanoparticles. According to an embodiment, the biodegradable elastic polymer may be formed of poly(lactide-co-ε-caprolactone) (PLCL). The biodegradable elastic polymer is not limited thereto, and various biodegradable elastic polymers other than the PLCL may be used. The nanoparticles may be formed of silicon oxide or polytetrafluoroethylene (PTFE). According to one embodiment, the nanoparticles may be formed of silicon dioxide or PTFE having an aspect ratio of 1 and a size of 100 to 200 nm. According to another embodiment, the nanoparticle may be provided as a silicon dioxide flake having an aspect ratio of 2 to 100, a width of 10 to 30 μm, and a thickness of 100 to 300 nm. The first superhydrophobic film 1100 may include a first base film 1110 and first micro-pillars 1120.

The first base film 1110 may have a predetermined area, and may be provided as a film having a thin thickness.

The first micro-pillars 1120 may have a predetermined height, and may be formed on a bottom surface of the first base film 1110. A plurality of first micro-pillars 1120 may be provided so as to be uniformly arranged. According to an embodiment, the first micro-pillars 1120 may be provided integrally with the first base film 1110. The first micro-pillars 1120 may be provided as cylinders having a predetermined length.

The second superhydrophobic film 1200 may have a predetermined area, and may be formed of the same material and in the same area as the first superhydrophobic film 1100 so as to face the first superhydrophobic film 1100 on an upper side of the first superhydrophobic film 1100. The second superhydrophobic film 1200 may include a second base film 1210 and second micro-pillars 1220.

The second base film 1210 may have a predetermined area, may be provided as a film having a thin thickness, and may face the first base film 1110.

The second micro-pillars 1220 may have a predetermined height, and may be formed on the second base film 1210. A plurality of second micro-pillars 1220 may be provided so as to be uniformly arranged. According to an embodiment, the second micro-pillars 1220 may be provided integrally with the second base film 1210. The second micro-pillars 1220 may be provided as cylinders having a predetermined length.

The electrode 1300 may have a meandering shape having a predetermined length, and may be located on one surface of the first superhydrophobic film 1100 facing the second superhydrophobic film 1200. According to an embodiment, the electrode 1300 may be provided as a magnesium (Mg) electrode having a thickness of 280 to 320 nm.

The light emitting device 1400 may be connected to the electrode 1300, and may generate light by a current applied from the electrode 1300. According to an embodiment, the light emitting device 1400 may be provided as an infrared micro-light emitting diode (μ-LED) having a thickness of 280 to 320 μm.

Hereinafter, a process of manufacturing the superhydrophobic light emitting module described above will be described in detail.

A silicon wafer may be spin-coated with poly(methyl methacrylate) (PMMA) and polyimide (PI) to prepare a temporary substrate, and an electrode may be deposited and patterned on the substrate by using an electron beam and photolithography, respectively. After a diluted PI (D-PI) layer having a thickness of 400 nm is spin-coated as a temporary upper insulator, a mesh pattern of the electrode may be defined by using dry reactive ion etching (RIE), and the substrate may be immersed in acetone to remove a PMMA layer, so that a device may be released. After the D-PI layer is removed by the dry reactive ion etching, a μ-LED may be electrically connected to the electrode by using silver conductive epoxy. After a wire is bonded to a contact pad, another CAP/P40 film may be chemically bonded to the device through an ultraviolet/ozone treatment (PSDP-UVT), and a PDMS mold may be removed so as to complete the manufacture. According to an embodiment, the poly(methyl methacrylate) may have a thickness of 90 to 110 nm, and the polyimide may have a thickness of 1 to 1.4 μm. The electrode may be provided as a magnesium (Mg) electrode having a thickness of 280 to 320 nm.

FIG. 23 is a view showing tension test performance of the superhydrophobic light emitting module according to the embodiment of the present invention. (A) shows an IR LED array of a superhydrophobic light emitting module in which a first superhydrophobic film and a second superhydrophobic film are provided as CAP/P40 films, and (B) shows the IR LED array when (A) is stretched by 100% (100% stretching).

Referring to FIG. 23, it may be found that the superhydrophobic light emitting module 1000 emits IR light from 13 different sources when a voltage of 5 V is applied (A), and it may be found that even after the superhydrophobic light emitting module 1000 is stretched by 100%, the IR LED array emits light without being changed from before the stretching (B).

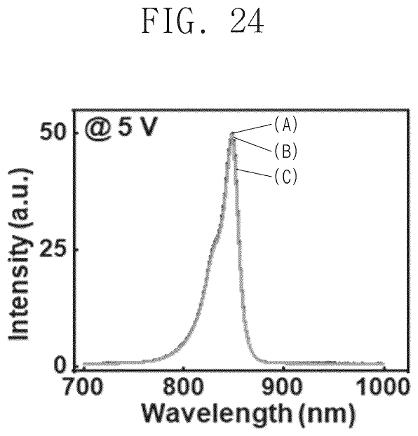

FIG. 24 is a graph showing the tension test performance of FIG. 23. (A) shows an infrared intensity (Intensity) according to a wavelength (Wavelength) of the superhydrophobic light emitting module when a voltage of 5 V is applied to the superhydrophobic light emitting module, (B) shows an infrared intensity according to a wavelength of the superhydrophobic light emitting module of (A) at tensile strain of 50%, and (C) shows an infrared intensity according to a wavelength of the superhydrophobic light emitting module of (A) at tensile strain of 100%.

Referring to FIG. 24, when the voltage of 5 V is applied to the superhydrophobic light emitting module, it may be found that the infrared intensity according to the wavelength before the superhydrophobic light emitting module 1000 is stretched (A) is consistent with the infrared intensity according to the wavelength when the superhydrophobic light emitting module 1000 is stretched by 50% (B) or 100% (C). Accordingly, tensile strain of the superhydrophobic light emitting module 1000 may not hinder physical and electrical behaviors of the superhydrophobic light emitting module 1000, and stable durability of the superhydrophobic light emitting module 1000, which is independent of the tensile strain, may be obtained.

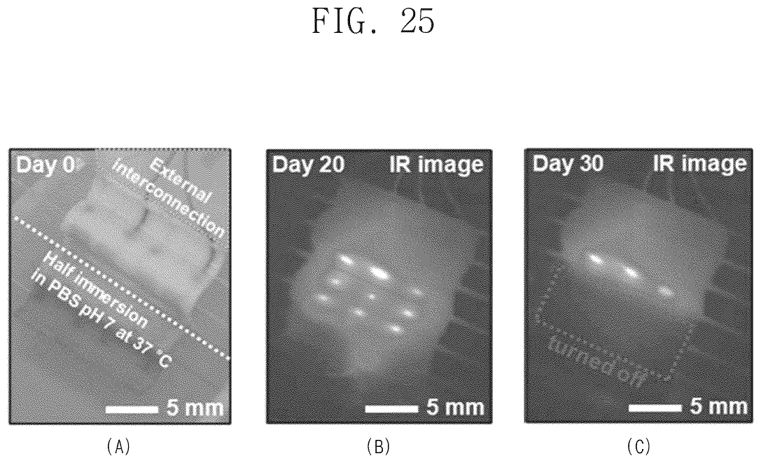

FIG. 25 is an image showing water permeability of the superhydrophobic light emitting module based on a CAP/P40 film according to the embodiment of the present invention.

Referring to FIG. 25, (A) is a state before immersing a portion (Half immersion) of the superhydrophobic light emitting module 1000 in a pH 7 PBS solution (phosphate-buffered saline) at 37° C., and the superhydrophobic light emitting module 1000 in the complete form may be found. (B) is a state when the portion of the superhydrophobic light emitting module 1000 is immersed in the pH 7 PBS solution at 37° C. for 480 h, and normal light emission of an infrared (IR) LED array may be found despite the immersion of the portion of the superhydrophobic light emitting module 1000. (C) is a state when the portion of the superhydrophobic light emitting module 1000 is immersed in the pH 7 PBS solution at 37° C. for 720 h, and it may be found that the infrared (IR) LED array in a region close to the immersed portion of the superhydrophobic light emitting module 1000 is turned off. Accordingly, it may be found that an electrical function is stably maintained even in water through an encapsulation function of the superhydrophobic light emitting module 1000 based on the CAP/P40 film.

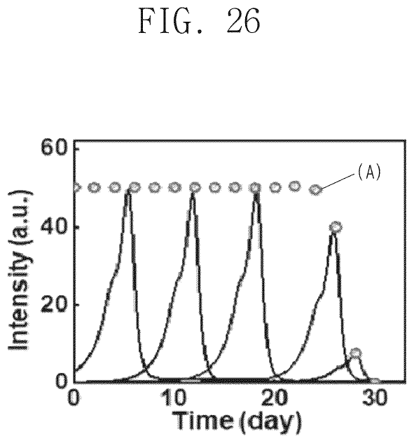

FIG. 26 is a graph showing water blocking characteristics of FIG. 25, which is measured by infrared spectroscopy (IR spectrum).

Referring to FIG. 26, when the superhydrophobic light emitting module 1000 based on the CAP/P40 film is immersed in the pH 7 PBS solution at 37° C., and a voltage of 5 V is applied, a peak intensity (Peak intensity) according to a time (Time) of the superhydrophobic light emitting module 1000 at a wavelength of 850 nm may be found (A). It may be found that a waveform and a peak intensity of an infrared spectrum are almost the same during an immersion period of 24 days, and performance deteriorates within a relatively short time after 24 days, which becomes 0 after 30 days.

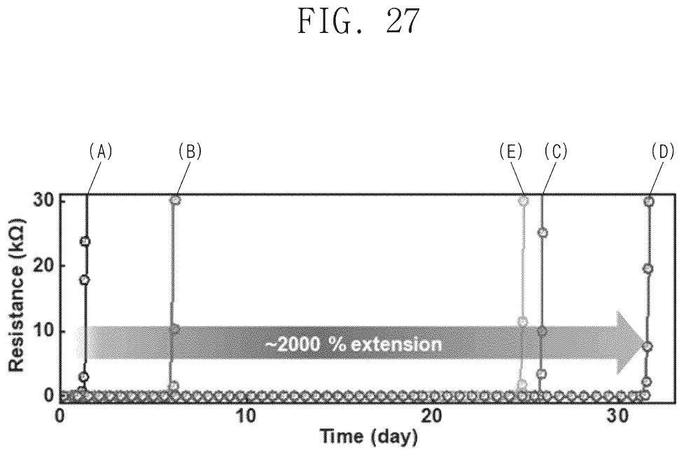

FIG. 27 is a graph showing solubility of superhydrophobic light emitting modules according to various embodiments. (A) shows a change in an electrical resistance measured by immersing a superhydrophobic light emitting module, which has a thickness of 300 μm and includes a first superhydrophobic film and a second superhydrophobic film formed of a biodegradable polymer that does not include micro-pillars (Pristine PLCL), in a pH 7 PBS solution at 37° C., (B) shows a change in an electrical resistance measured by immersing a superhydrophobic light emitting module, which has a thickness of 300 μm and includes a first superhydrophobic film and a second superhydrophobic film formed of a biodegradable polymer that includes micro-pillars (CAP/PO), in the pH 7 PBS solution at 37° C., (C) shows a change in an electrical resistance measured by immersing a superhydrophobic light emitting module, which has a thickness of 300 μm and includes a first superhydrophobic film and a second superhydrophobic film formed of a biodegradable polymer that does not include micro-pillars and is mixed with PTFE nanoparticles at a volume fraction of 40% (no pillar CAP/P40), in the pH 7 PBS solution at 37° C., (D) shows a change in an electrical resistance measured by immersing a superhydrophobic light emitting module, which has a thickness of 300 μm and includes a first superhydrophobic film and a second superhydrophobic film formed of a biodegradable polymer that includes micro-pillars and is mixed with PTFE nanoparticles at a volume fraction of 40% (CAP/P40), in the pH 7 PBS solution at 37° C., and (E) shows a change in an electrical resistance measured by immersing a superhydrophobic light emitting module, which has a thickness of 300 μm and includes a first superhydrophobic film and a second superhydrophobic film formed of a biodegradable polymer that includes micro-pillars and is mixed with silicon dioxide nanoparticles at a volume fraction of 40% (CAP/S40), in the pH 7 PBS solution at 37° C.

Referring to FIG. 27, water blocking performance may be found by immersing Pristine PLCL, CAP/PO, CAP/P40 (no pillar), CAP/P40, and CAP/S40 in the PBS solution, and measuring the electrical resistance.

It may be found that a lifetime of the superhydrophobic light emitting module based on the Pristine PLCL film (A) is 1.5 days, and when the biodegradable polymer that includes micro-pillars is adopted to the first superhydrophobic film and the second superhydrophobic film, each of which is provided as the Pristine PLCL film, it may be found that a lifetime of the superhydrophobic light emitting module based on the CAP/PO film (B) is extended to 6 days. In addition, when a configuration in which the PTFE nanoparticles are mixed in the biodegradable polymer that does not include micro-pillars at a volume fraction of 40% is adopted to the first superhydrophobic film and the second superhydrophobic film, each of which is provided as the Pristine PLCL film, it may be found that a lifetime of the superhydrophobic light emitting module based on the CAP/P40 (no pillar) film (C) is significantly extended to 25 days. In addition, when a configuration in which the PTFE nanoparticles are mixed in the biodegradable polymer that includes micro-pillars at a volume fraction of 40% is adopted to the first superhydrophobic film and the second superhydrophobic film, each of which is provided as the Pristine PLCL film, it may be found that a lifetime of the superhydrophobic light emitting module based on the CAP/P40 film (D) is implemented to be 30 days or more. Meanwhile, when a configuration in which the silicon dioxide nanoparticles are mixed in the biodegradable polymer that includes micro-pillars at a volume fraction of 40% is adopted to the first superhydrophobic film and the second superhydrophobic film, each of which is provided as the Pristine PLCL film, it may be found that a lifetime of the superhydrophobic light emitting module based on the CAP/S40 film (E) is longer than (A), but shorter than (D). This is due to hydrophilicity and solubility characteristics of the silicon dioxide nanoparticles included in the CAP/S40 film, and it may be found that the lifetime of the superhydrophobic light emitting module 1000 based on the CAP/P40 film is longer.

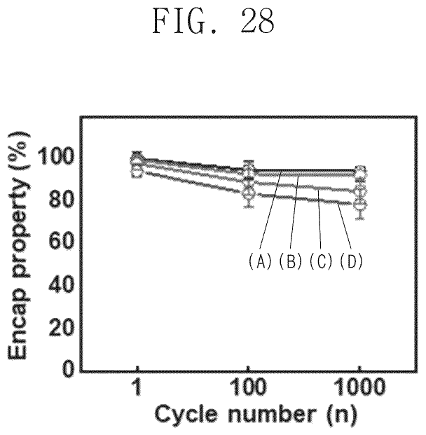

FIG. 28 is a graph showing encapsulation performance according to various tensile strain of the superhydrophobic light emitting module based on the CAP/P40 film according to the embodiment of the present invention. (A) shows an encapsulation property (Encap property) under 1000 cycles of loading (Cycle number) at tensile strain of 50% in the superhydrophobic light emitting module, (B) shows an encapsulation property under 1000 cycles of loading at tensile strain of 100% in the superhydrophobic light emitting module, (C) shows an encapsulation property under 1000 cycles of loading at tensile strain of 200% in the superhydrophobic light emitting module, and (D) shows an encapsulation property under 1000 cycles of loading at tensile strain of 300% in the superhydrophobic light emitting module.

Referring to FIG. 28, it may be found that the superhydrophobic light emitting module 1000 based on the CAP/P40 film maintains physical performance and electrical performance of the superhydrophobic light emitting module 1000 with high stretchability and protective performance of the CAP/P40 film at 1000 cycles of repeated deformations corresponding to tensile strain of 50%, 100%, 200%, and 300%.

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

What is claimed is:

1. A superhydrophobic film comprising:
a base film; and
a plurality of micro-pillars formed on the base film,
wherein the base film and the micro-pillar include a biodegradable polymer and nanoparticles.

2. The superhydrophobic film of claim 1, wherein the nanoparticle is formed of silicon oxide or polytetrafluoroethylene (PTFE).

3. The superhydrophobic film of claim 1, wherein the nanoparticle has an aspect ratio of 1 and a size of 100 to 200 nm.

4. The superhydrophobic film of claim 3, wherein a volume fraction of the nanoparticles to the polymer is 40%.

5. The superhydrophobic film of claim 1, wherein the nanoparticle is provided as a flake having an aspect ratio of 2 to 100, a width of 10 to 30 μm, and a thickness of 100 to 300 nm.

6. The superhydrophobic film of claim 5, wherein a volume fraction of the nanoparticles to the polymer is 20%.

7. A superhydrophobic light emitting module comprising:
a first superhydrophobic film;
a second superhydrophobic film facing the first superhydrophobic film;
an electrode provided on one surface of the first superhydrophobic film facing the second superhydrophobic film; and
a light emitting device connected to the electrode, and configured to generate light by a current applied from the electrode,
wherein each of the first superhydrophobic film and the second superhydrophobic film includes:
a base film; and
a plurality of micro-pillars formed on the base film, and
the base film and the micro-pillar include a biodegradable polymer and nanoparticles.

8. A method for manufacturing a superhydrophobic film, the method comprising:
preparing a mixed solution by mixing nanoparticles with a solution in which a biodegradable polymer is dissolved in an organic solvent;
preparing a superhydrophobic film by pouring the mixed solution into a mold; and
separating the superhydrophobic film from the mold, wherein the superhydrophobic film separated from the mold includes:
a base film; and
a plurality of micro-pillars formed on the base film.

9. The method of claim 8, wherein the biodegradable polymer is dissolved in the organic solvent at a mass ratio of 10 to 20, and
the nanoparticles are mixed with the solution at a volume fraction of 10 to 40.

10. The method of claim 8, wherein the nanoparticle has an aspect ratio of 1 and a size of 100 to 200 nm.

11. The method of claim 8, wherein the nanoparticle is provided as a flake having an aspect ratio of 2 to 100, a width of 10 to 30 μm, and a thickness of 100 to 300 nm.
